(19) United States
(12) Patent Application Publication
(10) Pub. No.: US 2011/0232720 A1
(43) Pub. Date: Sep. 29, 2011

(54) HIGH-CONCENTRATION PHOTOVOLTAIC SYSTEM

(76) Inventors: Aimone Balbo Di Vinadio, Chiusa San Michele (Torino) (IT); Mario Palazzetti, Chiusa San Michele (Torino) (IT)

(21) Appl. No.: 13/057,990

(22) PCT Filed: Aug. 7, 2008
(86) PCT No.: PCT/IT2008/000539

§ 371 Date: May 10, 2011

(51) Int. Cl. H01L 31/052

(52) U.S. Cl. 136/246

(57) ABSTRACT

A high-concentration photovoltaic system comprises at least one photovoltaic receiver (12) and a reflecting device (14) arranged for concentrating solar energy on said photovoltaic receiver (12). The photovoltaic receiver (12) comprises a tubular body (28) elongated in a longitudinal direction (30). The photovoltaic receiver (28) comprises a plurality of strips of photovoltaic material (32) fixed within said body (28). The supporting body (28) is provided with a plurality of lenses (34) arranged for focusing on said strips of photovoltaic material (32) the reflected solar radiation coming from said reflecting device (14).

The present invention relates to a high-concentration photovoltaic system.

In systems for the production of electrical energy by means of photovoltaic elements, it is desirable to obtain a high concentration of solar energy, both in order to reduce the amount of photovoltaic material used and to increase the efficiency and the yield of the photovoltaic system as well as rendering economically advantageous technologies that present a particularly high cost per unit surface but are able to operate with high efficiency.

The object of the present invention is to provide a photovoltaic system that will enable high concentrations of energy to be obtained with structures that present low costs, elegance and can also be integrated on buildings, and that moreover presents the possibility of recovering the heat associated to the processes of photovoltaic conversion.

According to the present invention, the above object is achieved by a photovoltaic system having the characteristics forming the subject of Claim 1.

The characteristics and advantages of the system according to the present invention will emerge clearly in the course of the detailed ensuing description, which is provided purely by way of non-limiting example, with reference to the attached drawings, wherein:

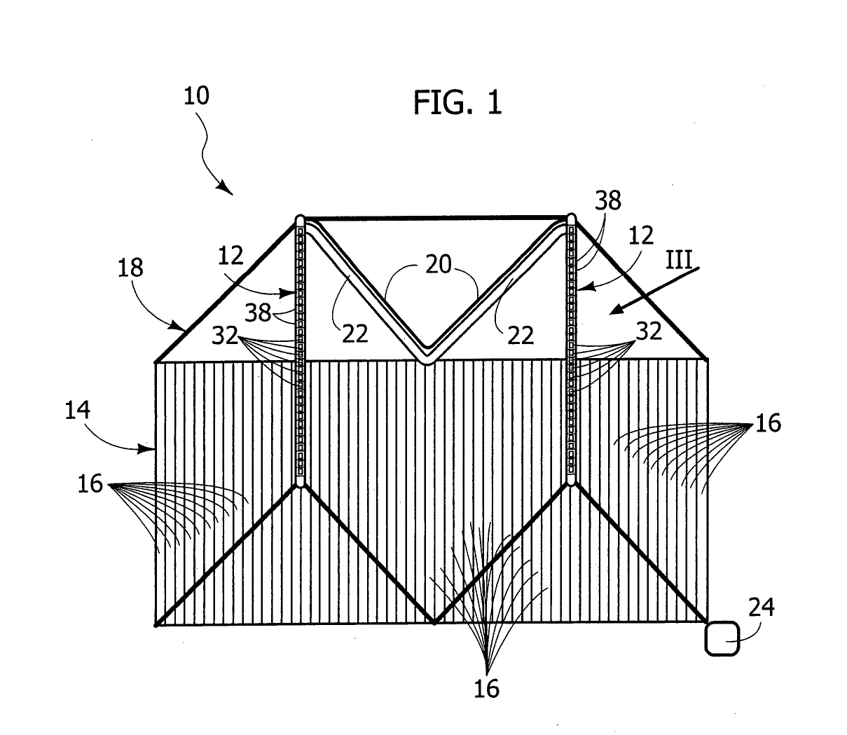

FIG. 1 is a schematic perspective view of a photovoltaic system according to the present invention;

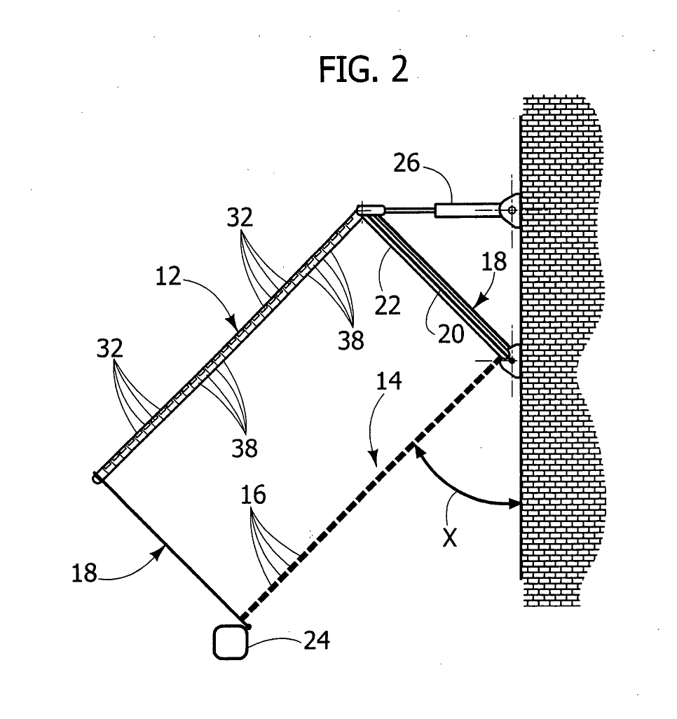

FIG. 2 is a schematic side view of the system of FIG. 1;

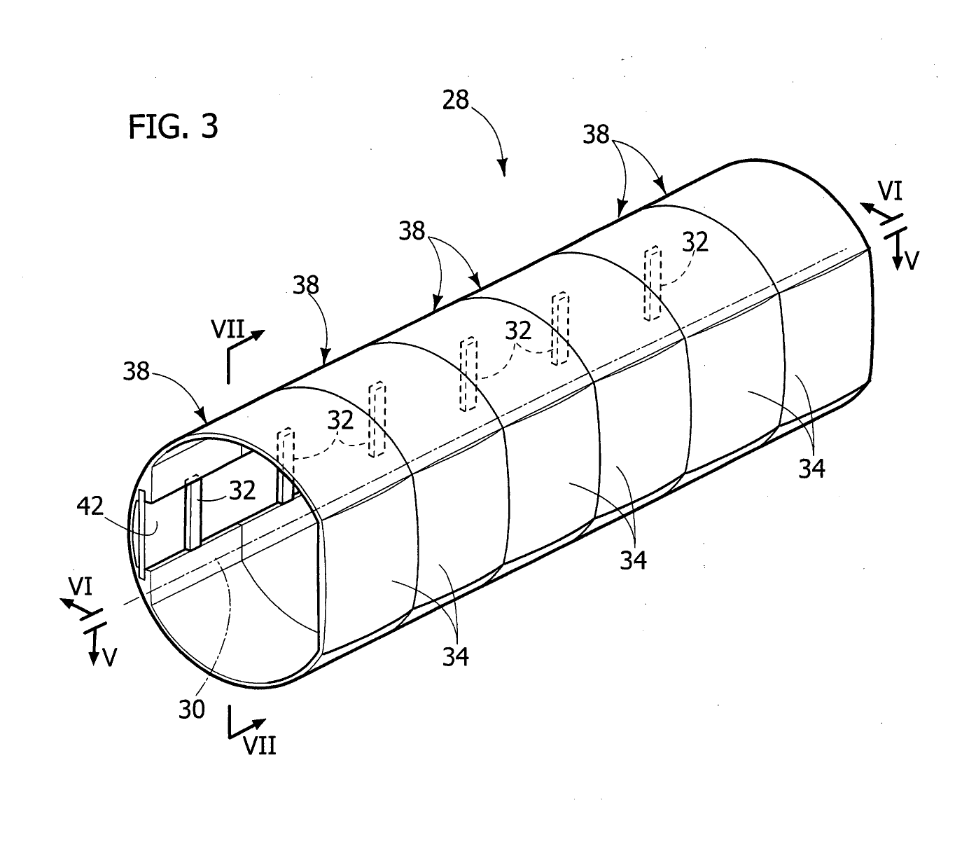

FIG. 3 is a partial perspective view and at a larger scale of the part indicated by the arrow III in FIG. 1;

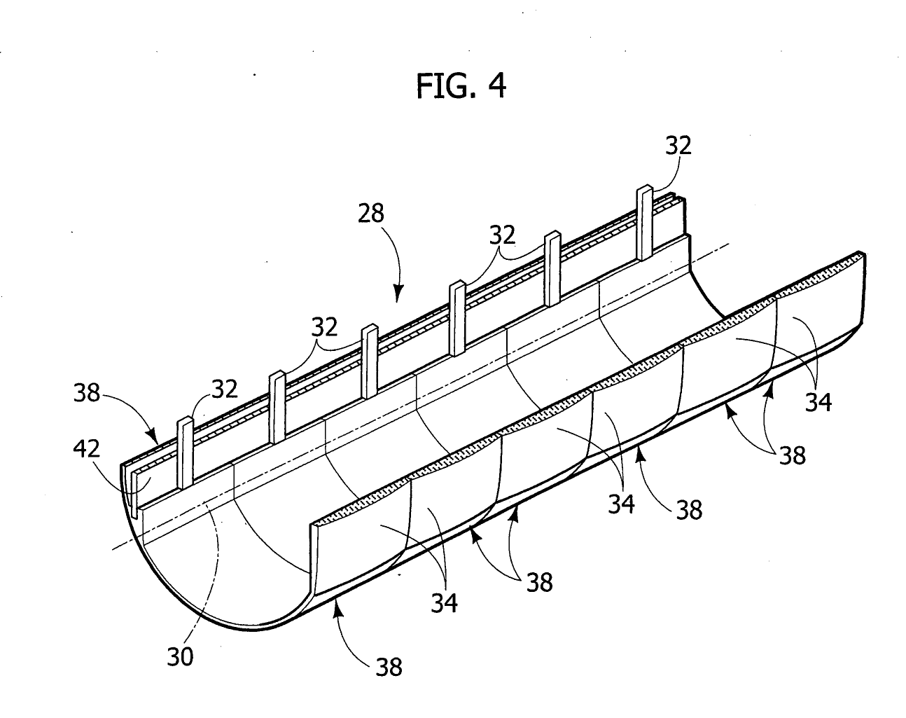

FIG. 4 is a sectioned perspective view of the receiver of FIG. 3;

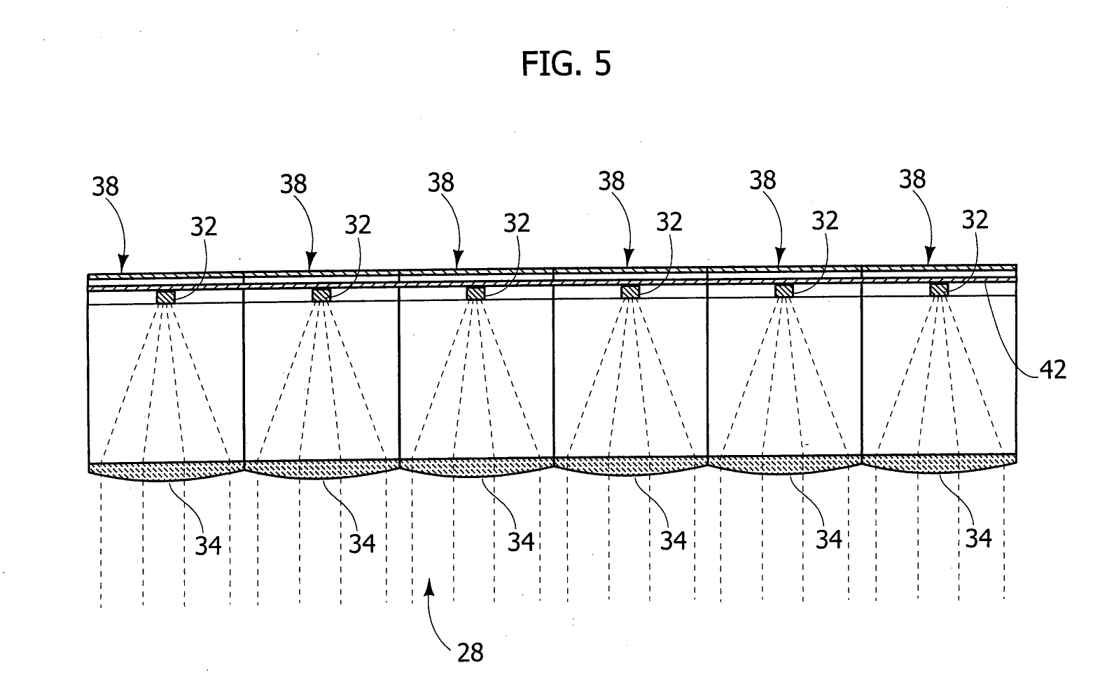

FIGS. 5, 6 and 7 are sections according to the lines V-V, VI-VI and VII-VII, respectively, of FIG. 3;

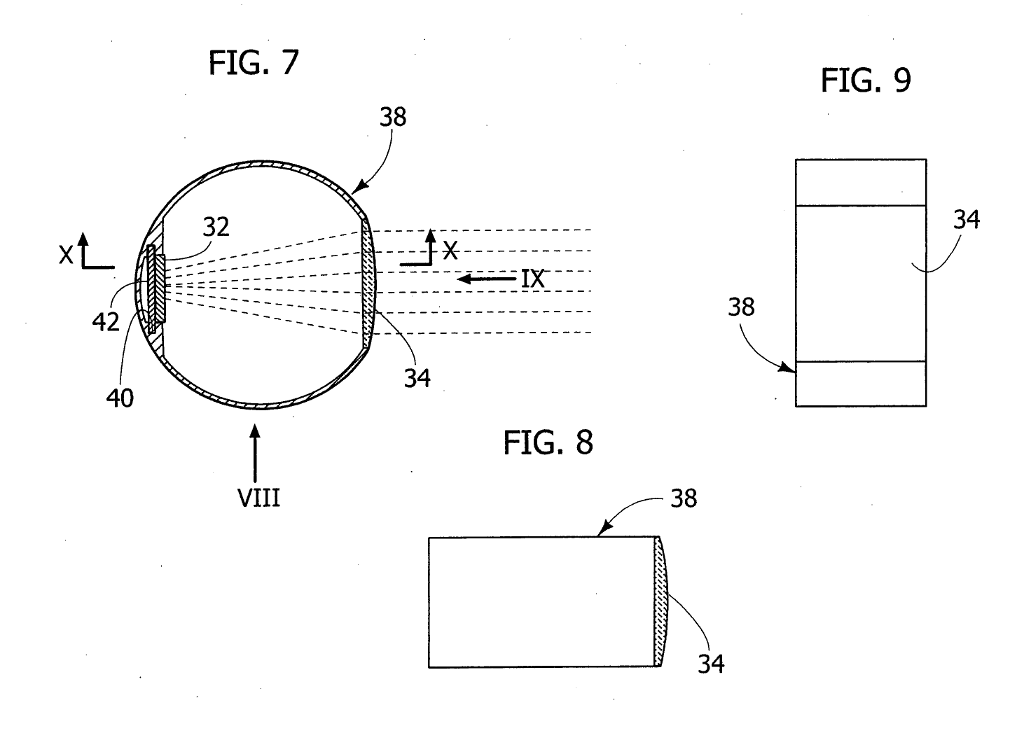

FIGS. 8 and 9 are views according to the arrows VIII and IX of FIG. 7;

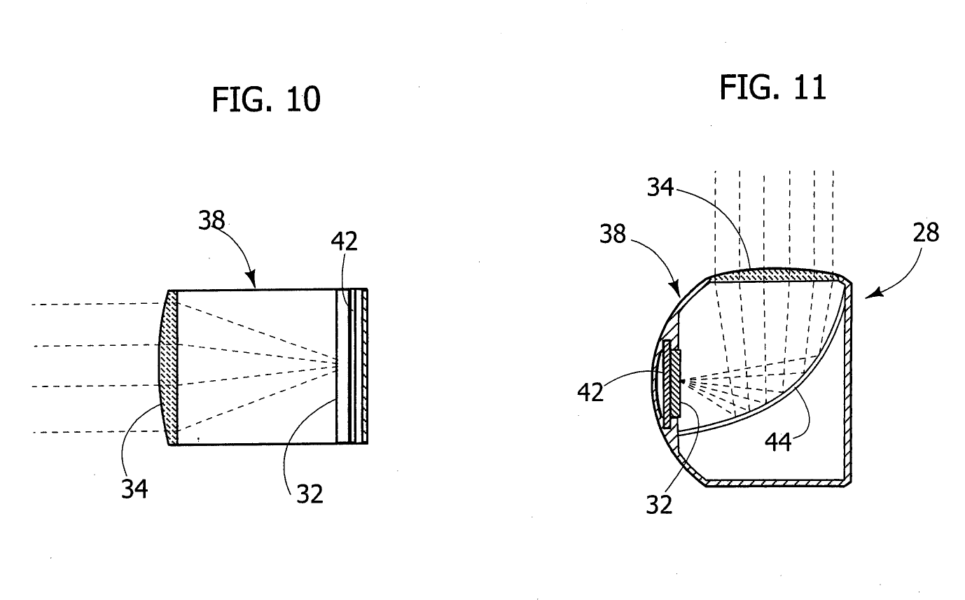

FIG. 10 is a section according to the line X-X of FIG. 7; and

FIG. 11 is a schematic cross section illustrating a variant of FIG. 7.

With reference to FIGS. 1 and 2, designated by 10 is a high-concentration photovoltaic system according to the present invention.

The photovoltaic system 10 comprises at least one photovoltaic receiver 12 and a reflecting device 14 arranged so as to concentrate solar energy on the photovoltaic receiver 12. In the example illustrated in the figures, two photovoltaic receivers 12 are provided, but it is understood that the number of said photovoltaic receivers may vary according to the requirements and/or the design variables.

The reflecting device 14 comprises a perimetral frame, supported on which is a plurality of elongated mirrors 16, each of which can be oriented about a respective axis parallel to its own longitudinal direction to keep the solar radiation constantly focused on a respective receiver 12. The axes of rotation of the mirrors 16 are parallel to one another. Preferably, the mirrors are strip-shaped plane mirrors.

The frame bearing the mirrors 16 moreover carries a supporting structure 18, fixed to which are the photovoltaic receivers 12, which are set at a fixed distance from the reflecting device 14. Each photovoltaic receiver 12 has an elongated shape and extends parallel to the reflecting surfaces of the mirrors 16. The length of the photovoltaic receivers 12 is substantially equal to the length of the mirrors 16. The supporting structure 18 comprises ducts 20 for passage of electrical conductors connected to the photovoltaic receivers and ducts 22 for passage of a coolant for the photovoltaic receivers 12.

Designated as a whole by 24 in FIGS. 1 and 2 is a pointing system, which, according to the position of the Sun, controls orientation of the mirrors 16 about the respective axes so that these will keep the reflected solar radiation constantly focused on the respective receivers 12. To enable orientation of the mirrors 16 about the respective axes there can, for example, be provided a single motor connected to the mirrors 16 by means of a rack system that transmits the same angle of rotation to all the mirrors, which can start from different initial angular positions so as to guarantee that the radiation reflected will always remain concentrated on the photovoltaic receivers 12 irrespective of the movement of the Sun. The frame bearing the mirrors 16 is articulated to a fixed wall about an axis orthogonal to the axes of rotation of the mirrors 16. The pointing system 24 controls an actuator designated as a whole by 26 in FIG. 2, which varies the angle of the reflecting device 14 with respect to a vertical plane for keeping the reflecting device 14 constantly orthogonal to the Sun. The actuator 26 varies the inclination of the plane containing the mirrors 16 with respect to a vertical plane to enable zenithal tracking of the movement of the Sun.

With reference to FIGS. 3 and 4, each photovoltaic receiver 12 comprises a tubular body 28 elongated in a longitudinal direction 30. Fixed within the body 28 is a plurality of strips of photovoltaic material 32, which extend in a direction transverse with respect to the longitudinal direction 30. The strips of photovoltaic material 32 are parallel to one another and set at a distance from one another in the longitudinal direction 30. The tubular body 28 is provided on its outer surface with a plurality of lenses 34. The lenses 34 receive the solar radiation reflected by the mirrors 16 and focus said solar radiation on the strips of photovoltaic material 32. Preferably provided is a lens 34 associated to each strip of photovoltaic material 32. The particular shape of the focal area 32 enables the production of strip-shaped photovoltaic elements, which are of particular interest in the production of photovoltaic cells.

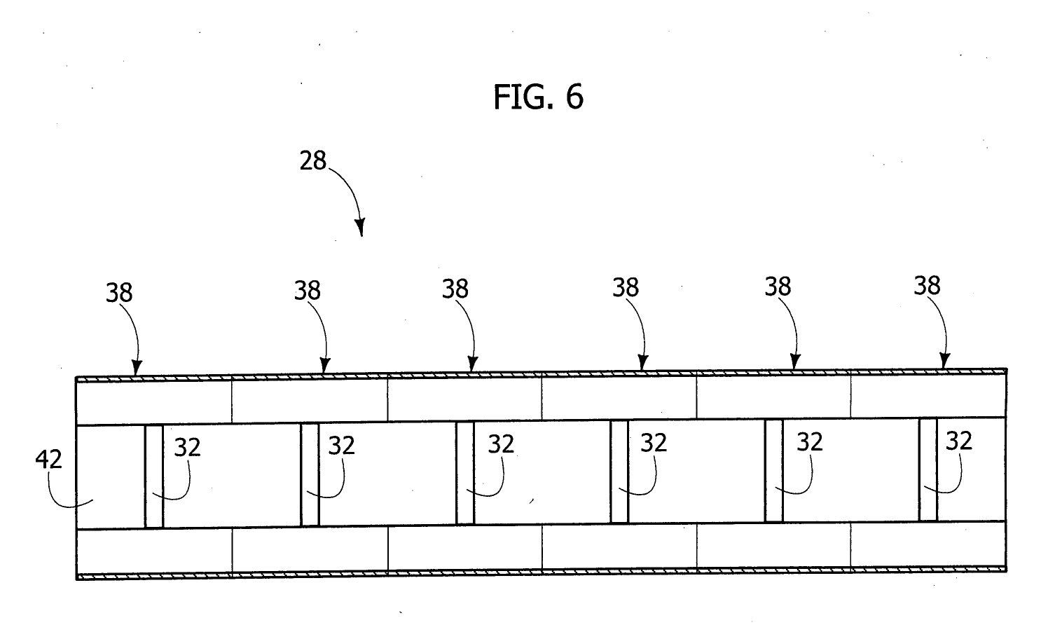

With reference to FIGS. 5 and 6 the lenses 34 occupy, in the longitudinal direction, the entire length of the tubular body 28, whilst the strips of photovoltaic material 32 occupy only a minimal part of the surface of the tubular body 28 parallel to the lenses 34. Even though the surface occupied by the strips of photovoltaic material 32 is very small, the entire solar radiation that impinges upon the lenses 34 is concentrated on the strips of photovoltaic material 32. This arrangement enables an extremely high concentration of solar energy per unit surface of the photovoltaic material to be obtained.

This high concentration of energy entails a considerable increase in temperature of the photovoltaic receiver 12. Said increase in temperature would have adverse consequences as regards the yield of the photovoltaic process. According to an advantageous characteristic of the present invention, the heat produced by the concentration of solar energy on the photovoltaic receiver 12 can be dissipated by means of a coolant that is made to circulate within the tubular body 28. The strips of photovoltaic material 32 are immersed in the coolant. The thermal energy that is extracted by the photovoltaic receiver 12 by means of the coolant can be used for the production of hot water, for example for domestic use. The area of the photovoltaic receiver 12 not exposed to the solar radiation can be thermally insulated for reducing the thermal dispersions towards the outer environment. The body 28 of the photovoltaic receiver 12 is hydraulically connected to the ducts 22 of the supporting structure 18 to enable a circulation of the coolant towards the outside.

From the constructional standpoint, the tubular body 28 can be formed by a plurality of sections 38 identical to one another, fixed to one another in an axial direction along the respective front edges. Each section 38 has a respective lens 34 and carries a respective strip of photovoltaic material 32. FIGS. 7 to 10 illustrate one of said sections 38. The sections can be made of injection-moulded plastic material and can be fixed to one another by means of gluing, welding, or the like. Each section 38 is provided with a seat 40 opposite to the lens 34. The seats 40 aligned with respect to one another form a longitudinal housing, inserted in which is a base shaped like a thin plate 42, fixed on which are the various strips 32 of photovoltaic material. The base 42 carries the electrical connections of the strips of photovoltaic material 32.

With reference to FIG. 11, in certain applications it could be desirable to reduce the dimensions in cross section of the photovoltaic receiver 12 to reduce the volume of the transparent thermovector liquid. For said purpose, inside the tubular body 28 there could be set a curved mirror 44, which receives the radiation from the lenses 34 and reflects it onto the strips, of photovoltaic material 32. This solution enables the photovoltaic receiver 12 to be made in a more compact form.

The photovoltaic system 10 can be used as shielding device on facades of buildings, for example, above windows or the like. In operation, the solar energy reflected by the mirrors 16 is concentrated on the lenses 34 of the receivers. The lenses 34 concentrate the solar radiation on the strips of photovoltaic material 32, obtaining a high concentration of energy. The flowrate of coolant will be high in such a way as to keep the temperature of the photovoltaic elements sufficiently low.

A further configuration of the above receiver, suited to systems with medium-to-low concentration, can be envisaged for housing, instead of a series of spherical lenses, just one cylindrical lens with longitudinal axis, which provides an elongated focal area in which strip-shaped photovoltaic elements elongated in the direction of the longitudinal axis of the receiver will be arranged.

1. A high-concentration photovoltaic system, comprising at least one photovoltaic receiver and a reflecting device arranged for concentrating solar energy on said photovoltaic receiver, characterized in that the photovoltaic receiver comprises a tubular body elongated in a longitudinal direction, housed in which is photovoltaic material, said supporting body being provided with at least one lens arranged for focusing on said photovoltaic material the reflected solar radiation coming from said reflecting device onto at least one strip-shaped focusing area.

2. The photovoltaic system according to claim 1, characterized in that it comprises a plurality of strips of photovoltaic material fixed within said body.

3. The photovoltaic system according to claim 2, characterized in that said strips of photovoltaic material are arranged transversely with respect to said longitudinal direction and are set at a distance from one another in said direction.

4. The photovoltaic system according to claim 3, characterized in that said supporting body comprises a plurality of spherical lenses.

5. The photovoltaic system according to claim 1, characterized in that it comprises at least one strip of photovoltaic material arranged parallel with respect to said longitudinal direction.

6. The photovoltaic system according to claim 1, characterized in that said supporting body comprises at least one cylindrical lens parallel to said longitudinal direction.

7. The photovoltaic system according to claim 1, characterized in that a coolant is made to flow within said tubular body.

8. The photovoltaic system according to claim 2, characterized in that each strip of photovoltaic material is associated to a respective lens.

9. The photovoltaic system according to claim 4, characterized in that said tubular body comprises a plurality of axial sections fixed to one another along respective front surfaces, each section having a respective lens.

10. The photovoltaic system according to claim 1, characterized in that housed within the tubular body is a mirror that receives the solar radiation focused by said lenses and reflects it onto said strips of photovoltaic material.

11. The photovoltaic system according to claim 1, characterized in that the reflecting device comprises a plurality of elongated mirrors parallel to one another, which can be oriented for keeping the solar radiation constantly focused on said receiver.

12. The photovoltaic system according to claim 11, characterized in that said photovoltaic receiver extends parallel to the reflecting surfaces of said mirrors.

13. The photovoltaic system according to claim 11, characterized in that it comprises a pointing and adjustment system with two degrees of freedom for orienting the reflecting device according to the azimuthal movement of the Sun and for orienting the individual mirrors about respective axes of rotation.

14. The photovoltaic system according to claim 1, characterized in that it comprises a supporting structure for supporting said at least one photovoltaic receiver at a fixed distance from said reflecting device.

15. The photovoltaic system according to claim 9, characterized in that said supporting structure comprises ducts for the passage of electrical conductors and for the passage of coolant.
